(19) United States
(12) Patent Application Publication
(10) Pub. No.: US 2012/0083205 A1
(43) Pub. Date: Apr. 5, 2012

(54) NFC DEVICE HAVING A DIFFERENTIAL INPUT ENVELOPE DETECTOR

(75) Inventors: Cristian Marcu, Albany, CA (US); Jafar Savoj, Sunnyvale, CA (US)

(73) Assignee: QUALCOMM INCORPORATED, San Diego, CA (US)

(21) Appl. No.: 12/897,520

(22) Filed: Oct. 4, 2010

(51) Int. Cl. H04B 5/00; H01P 11/00; H05K 13/00; H03D 1/00

(52) U.S. Cl. 455/41.1; 329/315; 29/600; 29/825

(57) ABSTRACT

A differential input envelope detector receives an unamplified Near Field Communication (NFC) input signal from an NFC antenna and downconverts an NFC intelligence signal to baseband. In one example, the NFC input signal includes the NFC intelligence signal modulated onto a carrier. The differential input envelope detector downconverts and outputs the downconverted NFC intelligence signal onto an output node in such a way that the fundamental and odd harmonics of the carrier are canceled on the output node. There is substantially no signal of the frequency of the carrier present on the output node and this facilitates filtering of the downconverted NFC intelligence signal from interference and data recovery. An NFC data recovery circuit receives the downconverted NFC intelligence signal from the envelope detector output node. The NFC data recovery circuit can be a low power digital circuit involving an ultra-low power ADC and subsequent low power digital processing circuitry.

### BACKGROUND INFORMATION

1. Technical Field

The present disclosure relates to Near Field Communication (NFC) devices and methods.

2. Background Information

Near Field Communication (NFC) is an open-platform, standards-based, short-range, high frequency wireless communication technology that enables the bidirectional exchange of information between NFC devices over about a ten centimeter distance. NFC devices communicate via magnetic field induction. Each NFC device has an NFC loop antenna. When the antennas of two NFC devices are within each other's near field, they effectively form an air-core transformer that operates in a globally available and unlicensed radio frequency band. The near-field is an area around the antenna in which electromagnetic fields exist but may not propagate or radiate away from the antenna. They are typically confined to a volume that is approximately the same as the physical volume of the antenna. Various standards such as ISO/IEC 18902 (ECMA 340) and ISO/IEC 21481 apply to NFC devices. In one operational scenario, a first NFC device operates in an active mode and initiates communication with a second NFC device operating in a passive mode. The active device drives its antenna thereby generating a radio frequency (RF) field. The second device, which is known as the target device, need not use any internal power source. Rather, the second device captures energy from the RF field created by the first NFC device. The second device then uses this captured energy to reply by load modulating its antenna. The first device detects the effects of this load modulation. In this way, the first device receives information back from the second device even though the second device is operating in its passive mode. Ways of improving the performance of such NFC devices are desired.

### SUMMARY

A differential input envelope detector receives an unamplified Near Field Communication (NFC) input signal from an NFC antenna and downconverts an NFC intelligence signal to baseband. In one example, the NFC input signal includes the NFC intelligence signal modulated onto a carrier. The differential input envelope detector downconverts and outputs the downconverted NFC intelligence signal onto an output node in such a way that the fundamental and odd harmonics of the carrier are canceled on the output node. Accordingly, there is substantially no signal of the frequency of the carrier present on the output node and this facilitates data recovery and filtering of the downconverted NFC intelligence signal from interference. An NFC data recovery circuit receives the downconverted NFC intelligence signal from the envelope detector output node.

In one example, the NFC data recovery circuit is a digital circuit that involves an ultra-low power Analog-to-Digital Converter (ADC) and a low power digital processing circuit. Performing more of the data recovery operation using digital circuitry reduces power consumption as compared to conventional data recovery circuits that employ more analog circuitry. Not only does this reduce power consumption, but it also reduces integrated circuit area, increases design flexibility, eases portability across CMOS process nodes, and takes advantage of the raw speed of fine CMOS processes. In one especially advantageous embodiment, the ultra-low power ADC is a Successive Approximation ADC of a special design and the low power digital processing circuit involves a Mueller-Muller processing circuit. An NFC integrated circuit that is part of a cellular telephone handset system has a pair of terminals adapted to receive an unamplified differential NFC input signal from an NFC antenna. Two input leads of the differential input source follower envelope detector are coupled to the two terminals of the integrated circuit, and an output lead of the differential input source follower envelope detector is coupled to an input lead of the NFC data recovery circuit.

In another example, the NFC data recovery circuit is an analog circuit that involves an analog DC offset removal circuit, an operational amplifier that subtracts the DC offset from the NFC input signal, and a comparator that compares the signal as output from the operational amplifier with a reference voltage to generate extracted digital output bits.

The foregoing is a summary and thus contains, by necessity, simplifications, generalizations and omissions of detail; consequently, those skilled in the art will appreciate that the summary is illustrative only and does not purport to be limiting in any way. Other aspects, inventive features, and advantages of the devices and/or processes described herein, as defined solely by the claims, will become apparent in the non-limiting detailed description set forth herein.

### BRIEF DESCRIPTION OF THE DRAWINGS

FIG. 1 is a simplified diagram of a system that includes a specific embodiment of a Near Field Communication (NFC) integrated circuit in accordance with one novel aspect.

FIG. 2 is a more detailed diagram of a digital embodiment of the NFC integrated circuit of FIG. 1.

FIG. 3 is a circuit diagram of a single-ended input source follower envelope detector that may be used in the NFC integrated circuit of FIG. 1.

FIG. 4 is a diagram that shows the signal components present on the output node of the single-ended input source follower envelope detector of FIG. 3.

FIG. 5 is a diagram that shows how the amplitudes of the signal components present on the output node of the single-ended input source follower envelope detector of FIG. 3 change as the amplitude of the NFC input signal decreases.

FIG. 6 is a set of four waveforms of the signal on the output node of the single-ended input source follower envelope detector of FIG. 3 when a square wave NFC intelligence signal having an initial low portion followed by a high portion is received onto the NFC antenna at four different NFC input signal strengths.

FIG. 7 is a diagram of a differential input source follower envelope detector that is employed in the NFC integrated circuit of FIG. 1.

FIG. 8 is a diagram that shows the signal components present on the output node of the differential input source follower envelope detector of FIG. 7.

FIG. 9 is a diagram that shows how the amplitudes of the signal components present on the output node of the differential input source follower envelope detector of FIG. 7 change as the amplitude of the NFC input signal decreases.

FIG. 10 is a set of four waveforms of the signal on the output node of the differential input source follower envelope detector of FIG. 7 when a square wave NFC intelligence signal having an initial low portion followed by a high portion is received onto the NFC antenna at four different NFC input signal strengths.

FIG. 11 is a circuit diagram of one example of the matching network of the system of FIG. 1.

FIG. 12 is a circuit diagram of one example of an ADC that can be employed for the ADC in the digital embodiment of the system of FIG. 1.

FIG. 13 is a diagram of an example of the data recovery circuitry in the digital embodiment of the system of FIG. 1.

FIG. 14 is a circuit diagram of the Mueller-Muller processing circuit of the data recovery circuitry of FIG. 13.

FIG. 15 is a diagram of an example of the NFC data recovery circuit in an analog embodiment of the system of FIG. 1.

FIG. 16 is a flowchart of a method in accordance with one novel aspect.

### DETAILED DESCRIPTION

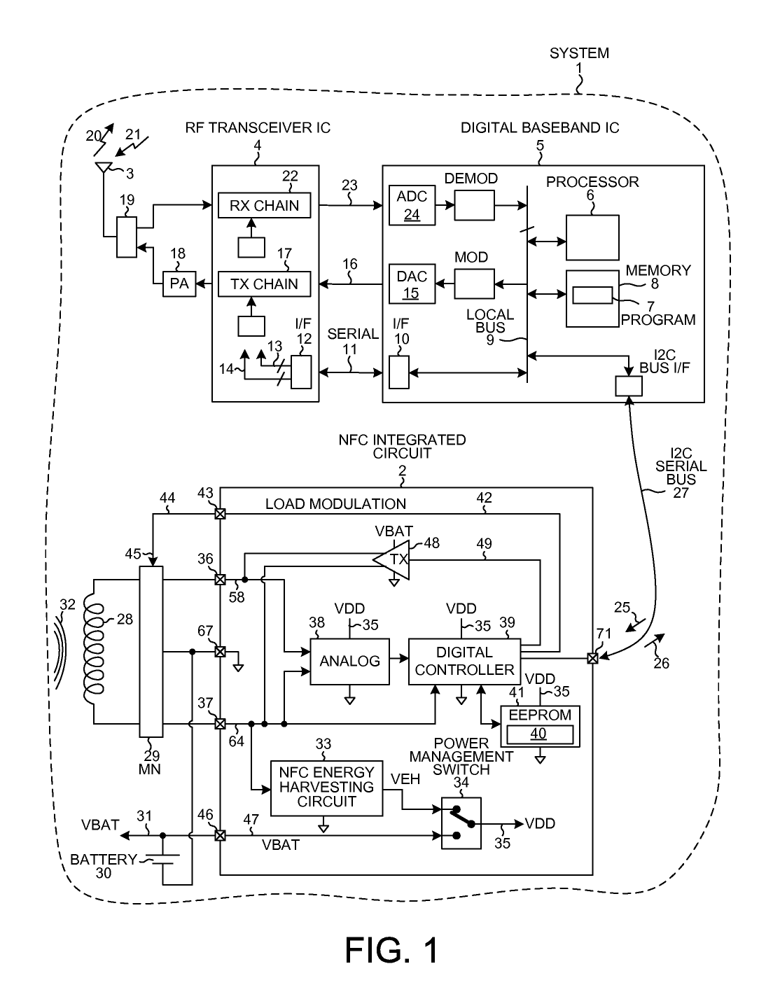

FIG. 1 is a high-level simplified diagram of a system 1 that includes a specific embodiment of a Near Field Communication (NFC) integrated circuit 2 in accordance with a first novel aspect. The system 1 in this example is a mobile communication device such as a cellular telephone handset. The particular cellular telephone handset functionality portion of system 1 includes (among other parts not illustrated) an antenna 3 usable for receiving and transmitting cellular telephone communications, an RF (Radio Frequency) transceiver integrated circuit 4, and a digital baseband processor integrated circuit 5. Digital baseband integrated circuit 5 includes a processor 6 that executes a program 7 of processor-executable instructions. Program 7 is stored in a processor-readable medium 8 that in this case is a semiconductor memory. Processor 6 accesses memory 8 via local bus 9. Processor 6 interacts with and controls the RF transceiver integrated circuit 4 by sending control information to integrated circuit 4 via serial bus interface 10, serial bus 11, serial bus interface 12, and groups of control conductors 13 and 14.

Cellular telephone information to be transmitted is modulated and is then converted into digital form on digital baseband processor integrated circuit 5 by a Digital-to-Analog Converter (DAC) 15. The resulting analog information is communicated across conductors 16 to the transmitter portion 17 of RF transceiver integrated circuit 4. The information is upconverted in frequency and is amplified by a power amplifier 18 and passes through a duplexer 19 and onto antenna 3 for transmission as a cellular telephone communication 20. Information received in the form of a cellular telephone communication 21 is received onto antenna 3. The information passes through the duplexer 19, is downconverted in frequency by a receiver portion 22 of the RF transceiver integrated circuit 4, and passes across conductors 23 to an Analog-to-Digital Converter (ADC) 24. The resulting digital information is demodulated and is supplied to processor 6. This particular cellular telephone functionality is but one example of a part of a system that operates with NFC integrated circuit 2. This explanation of the cellular telephone functionality is provided here to describe an example of a circuit that works in conjunction with NFC integrated circuit 2 in one embodiment.

In the particular system 1, the processor 6 in the digital baseband integrated circuit 5 can communicate with and can control the NFC integrated circuit 2 by communicating information 25 and 26 back and forth across serial bus 27. The NFC integrated circuit 2 is part of an NFC circuit within system 1. The NFC circuit includes an NFC loop antenna 28, a matching network 29, and the NFC integrated circuit 2. NFC antenna 28 in one example involves a set of inductive loops and is fabricated to be part or attached to the plastic outer case of the cellular telephone. In another example, NFC antenna 28 is realized as metal traces on a printed circuit board within the cellular telephone that carries the integrated circuits 4, 5 and 2 and other components. In FIG. 1, battery symbol 30 represents a system battery that powers the overall system 1. A supply voltage VBAT is supplied from battery 30 by conductor 31 to the digital baseband integrated circuit 5, the RF transceiver integrated circuit 4, and power amplifier 18, as well as to the NFC integrated circuit 2 as illustrated.

In a passive mode of operation of the NFC circuitry, the NFC circuitry is able to receive an NFC communication 32 onto antenna 28, to harvest energy from the NFC communication, and to use the harvested energy to recover digital information encoded in the NFC communication. Block 33 represents an NFC energy harvesting circuit. In the passive mode, a supply voltage VEH of approximately 1.0 volts at 10-20 microamperes as output by the NFC energy harvesting circuit 33 is supplied via power management switch 34 and supply voltage conductor 35 to other circuitry of the NFC integrated circuit 2 as illustrated. Signals from the NFC antenna 28 pass through matching network 29 and terminals 36 and 37 to an analog receiver 38. Subsequent processing and decision making is performed by a digital controller 39. Depending on the digital information recovered from the communication 32, the NFC circuitry communicates information back to an interrogating NFC device that originally made the NFC communication 32. In one example, the information communicated back includes information 40 stored in nonvolatile memory (EEPROM) 41 on the NFC integrated circuit 2. The information 40 is communicated back by load modulating the antenna. Digital controller 39 load modulates the antenna by outputting a single digital control bit signal LOAD MODULATION on conductor 42. This signal passes through terminal 43 and conductor 44 to input terminal 45 of matching network 29. The value of the digital control bit determines the loading on the antenna and this loading is detected by the interrogating NFC device as is known in the art. In the passive mode, the NFC integrated circuit 2 may be receiving no power from battery 30. Moreover, battery 30 may be discharged to the extent that the cellular telephone portion of the system 1 is not functioning. All processing necessary to receive the communication 32, to recover the digital information it carries, and to respond back to the interrogator using load modulation as described above is powered from energy harvested from the NFC communication itself and no processing is performed outside of NFC integrated circuit 2.

NFC integrated circuit 2 is also operable in an active mode. In the active mode, NFC integrated circuit 2 is powered partially or totally by energy from battery 30. The supply voltage VBAT from the battery is supplied via terminal 46, conductor 47, power management switch 34, and supply voltage conductor 35 to other circuitry of the NFC integrated circuit 2 as illustrated. In addition, the processor 6 of the system 1 is powered by battery 30 and is available to perform processing and decision making to carry out the NFC communication. Some of the active mode data recovery and protocol processing operations of the NFC communication are, in some embodiments, performed by processor 6. If the NFC integrated circuit 2 is to communicate information back to the interrogator, then an active transmitter 48 is made to drive antenna 28 to generate a radio frequency (RF) field. Active transmitter 48 is powered directly from the battery 30 as indicated by the label “VBAT” on its supply voltage lead. Digital controller 39 drives the antenna 28 by outputting a single digital control bit signal onto conductor 49. Active transmitter 48 converts this single digital bit into a differential signal that is supplied via terminals 36 and 37, and matching network 29, to antenna 28.

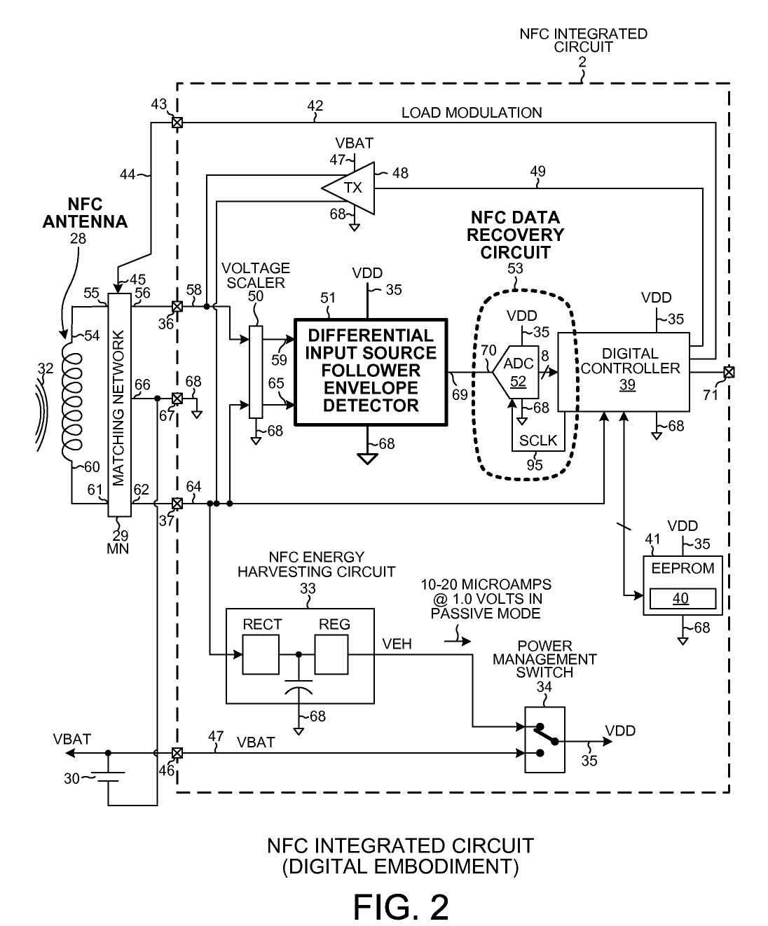

FIG. 2 is a more detailed diagram of NFC integrated circuit 2. The analog receiver portion 38 of FIG. 1 is shown in more detail in FIG. 2 as including a voltage scaler 50, a differential input source follower envelope detector 51, and an Analog-to-Digital Converter (ADC) 52. There is no intervening amplifier between the antenna 28 and the envelope detector 51 that amplifies RF frequency signals, but rather the envelope detector 51 receives the NFC input signal from the antenna in unamplified form and performs frequency demodulation to downconvert an NFC intelligence signal carried in the NFC input signal from RF frequencies down to baseband.

The ADC 52 and an amount of digital circuitry in the digital controller 39 are together referred to here as the NFC data recovery circuit 53. A first signal from a first terminal 54 of NFC antenna 28 passes through the matching network 29 from terminal 55 to terminal 56 and onto terminal 36 of NFC integrated circuit 2. From terminal 36 the first signal passes through conductor 58, and through voltage scaler 50, and to a first input lead 59 of the differential input source follower envelope detector 51. A second signal from a second terminal 60 of NFC antenna 28 passes through the matching network 29 from terminal 61 to terminal 62 and onto terminal 37 of NFC integrated circuit 2. From terminal 37 the second signal passes through conductor 64, and through voltage scaler 50, and to a second input lead 65 of the differential input source follower envelope detector 51. The first and second signals are due to an induced current flowing in NFC antenna 28 and may be considered a single differential voltage input signal at RF frequency. If the voltage of the first signal increases, then the voltage of the second signal decreases, and vice versa. The differential voltage input signal at RF frequency includes the strong 13.56 MHz carrier signal and a surrounding weaker NFC intelligence signal that has a one MHz bandwidth centered at the carrier frequency.

The matching network 29 includes a terminal 66 that is coupled to the ground terminal of battery 30 and to a ground terminal 67 of NFC integrated circuit 2. Ground terminal 67 is in turn coupled by a ground conductor 68 to the various sub-circuits of the NFC integrated circuit 2 as illustrated. Matching network 29 receives incoming load modulation control information via terminal 45.

Differential input source follower envelope detector 51 outputs its frequency downconverted analog signal via output lead 69 onto an input lead 70 of ADC 52. ADC 52 digitizes the analog signal at discrete times, thereby generating a corresponding stream of eight-bit digital values. The eight-bit digital values are supplied to digital controller 39 for further processing. Digital controller 39 includes serial bus interface and protocol processing circuitry. This circuitry communicates with the digital baseband integrated circuit 5 in serial fashion via serial interface terminal 71.

The terminal symbols 43, 36, 67, 37, 36 and 71 may represent pads or microbumps or other terminals on the integrated circuit die, or may represent pins, bond balls, tabs, leads or other terminals of a packaged integrated circuit. The dashed line identified with reference numeral 2 can represent either an integrated circuit die or a packaged integrated circuit.

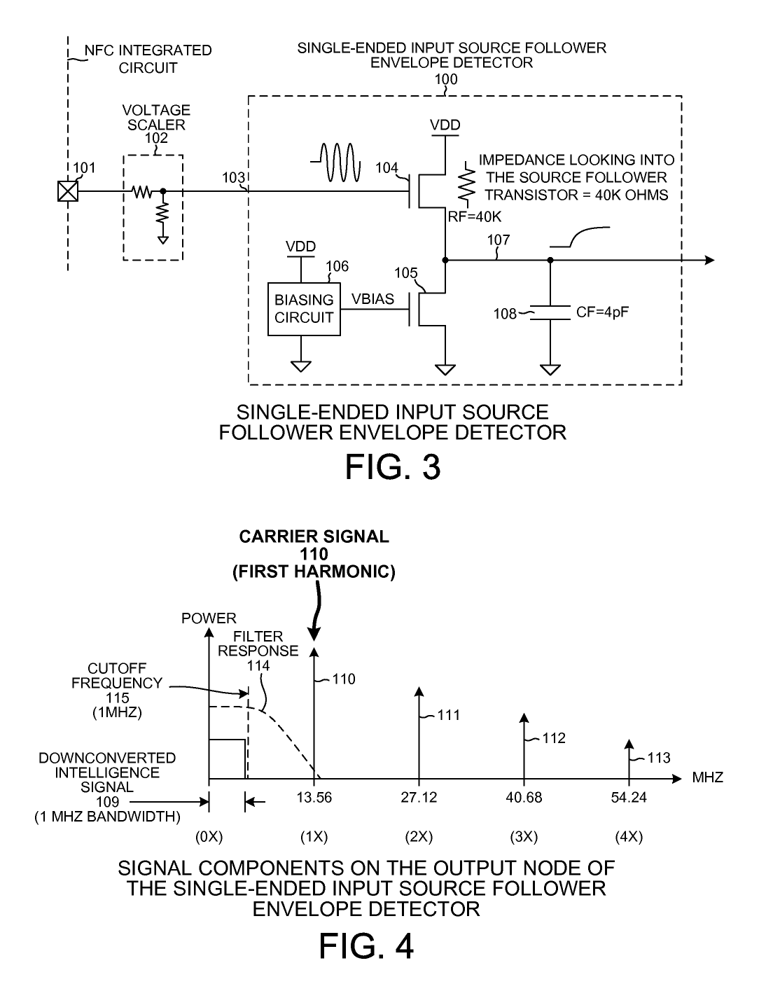

FIG. 3 is a simplified circuit diagram of a single-ended input source follower envelope detector circuit 100 as could be used to receive NFC communications. A signal from one end of a differential NFC antenna is received via a matching network onto an integrated circuit terminal 101. The signal passes through a voltage scaler 102 and onto an input lead 103 of the single-ended input envelope detector 100. The main input transistor 104 is biased by a biasing circuit involving a bias transistor 105 and a biasing circuit 106. Biasing circuit 106 provides a bias voltage VBIAS onto the gate of bias transistor 105 so that bias transistor 105 will draw a one microampere bias current from output node 107. The single-ended input envelope detector 100 includes a low pass RC filter. This RC filter involves the capacitance CF of a capacitor 108 and the impedance RF looking back into the detector from node 107.

In this example, the NFC signal as received onto the NFC antenna includes an NFC intelligence signal that is modulated onto a higher frequency carrier signal. The NFC intelligence signal has a low bandwidth of approximately one MHz. The carrier signal has a frequency of 13.56 MHz. The envelope detector 100 frequency demodulates the NFC signal to downconvert the one 1 MHz wide NFC intelligence signal from RF frequency down to baseband without using frequency mixers.

FIG. 4 is a diagram of the spectrum of the output signal on output node 107. Note that the NFC intelligence signal 109 is now downconverted to baseband frequency whereas the carrier signal 110 remains at the RF frequency of 13.56 MHz. The RC filter of the single-ended envelope detector is to pass the downconverted one MHz NFC intelligence signal but is to attenuate the 13.56 MHz carrier signal as much as is reasonably possible. Due to nonlinearities of the envelope detector, harmonics of the carrier signal are present on output node 107. These harmonics include the carrier 110 itself (the fundamental at a frequency of 1X), the second harmonic 111 at a frequency of 2X, the third harmonic 112 at a frequency of 3X, the fourth harmonic 113 at a frequency of 4X, and so forth. In this notation, the “X” denotes the 13.56 MHz frequency of the carrier. The dashed line 114 in FIG. 4 illustrates the filter response of the RC filter. Due to low power requirements in the passive mode, achieving good rejection of the carrier signal 110 and at the same time passing the downconverted intelligence signal 109 can be difficult using the simple RC filter of the circuit of FIG. 3. The RC filter has a finite rejection so in order to reject as much of the carrier as possible, the cutoff frequency of the RC filter is set to a frequency as low as possible between one MHz and 13.56 MHz. In the present example, the RC filter has roll-off of 20 dB/decade and a cutoff frequency 115 of one MHz. The impedance RF of the RC filter is 40K ohms and the capacitance CF is 4 pF.

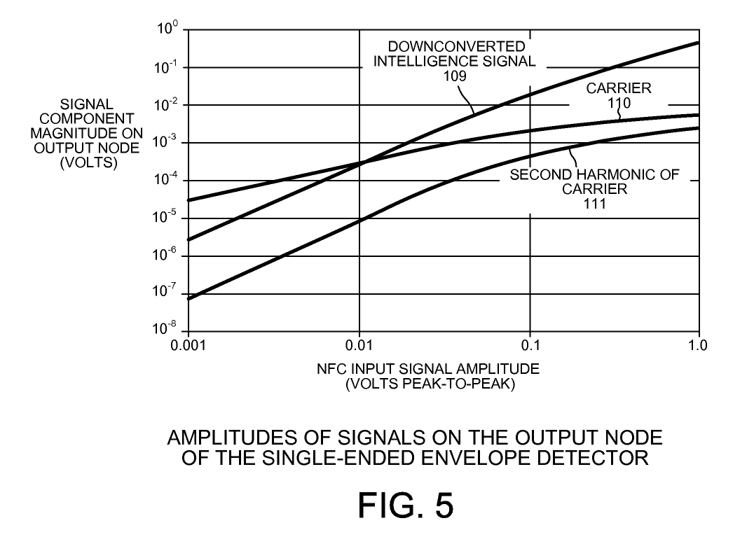

FIG. 5 is a diagram that illustrates an operation of the single-ended input envelope detector of FIG. 3. The vertical axis represents the voltage amplitude of a signal component on output node 107. The horizontal axis represents the peak-to-peak voltage amplitude of the NFC input signal supplied to the envelope detector. Proceeding from right to left in the diagram of FIG. 5 corresponds to decreasing the amplitude of the NFC input signal supplied to the envelope detector. The horizontal axis has a logarithmic scale. As the magnitude of the NFC input signal decreases proceeding from right to left in the diagram, the amplitude of the carrier component 110 on output node 107 is seen to decrease in amplitude at a slower rate than the amplitude of the downconverted NFC intelligence signal 109 until the lines marked 110 and 109 in FIG. 5 cross. For NFC input signal amplitudes below the NFC input signal amplitude where the lines cross, the carrier 110 on the output node 107 is of higher amplitude than the downconverted intelligence signal 109. The low amplitude of the downconverted intelligence signal 109 versus the amplitude of the carrier 110 makes filtering out the carrier difficult at low input signal levels.

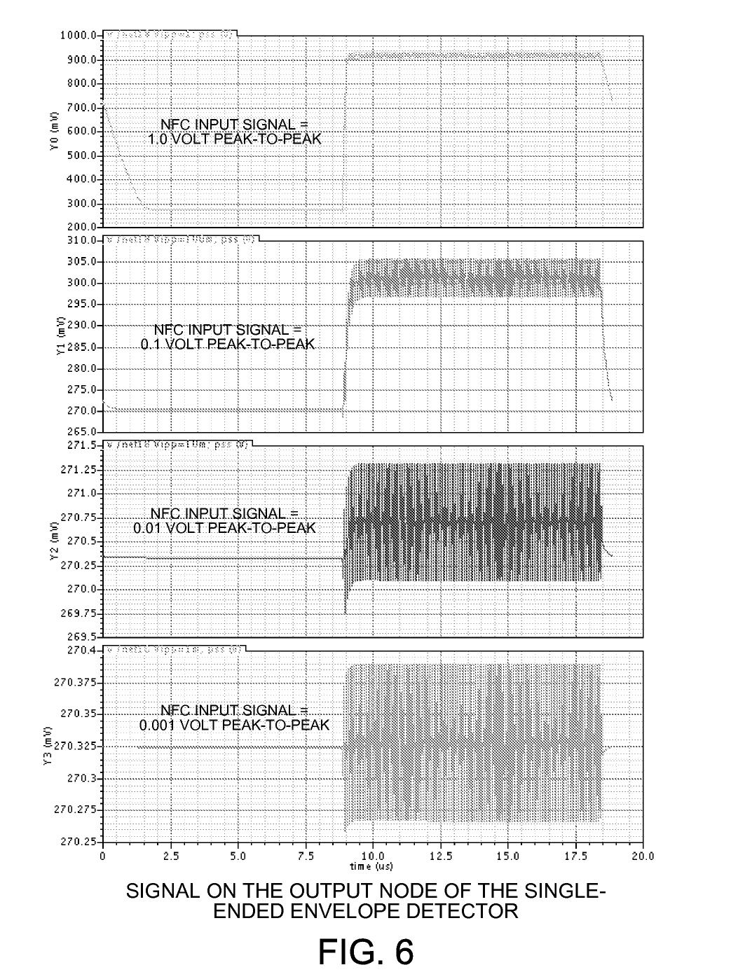

FIG. 6 is a set of four waveforms of the signal on output node 107 when a square wave intelligence signal having an initial low portion followed by a high portion is received onto the NFC antenna. The peak-to-peak input signal amplitudes for the waveforms from top to bottom in FIG. 6 are 1.0 volt, 0.1 volts, 0.01 volts, and 0.001 volts. Note that the relative amount of carrier signal interference riding on the downconverted intelligence signal as output from the envelope detector increases as the amplitude of the input signal decreases until separating the intelligence signal from the carrier interference in the case of the lowest diagram is almost impossible. Due to the difficulty of receiving at low input signal strength, the distance between active mode interrogating device and the passive mode receiving target device over which the NFC communication will work is limited. Additional filtering can be employed to attenuate the carrier, but providing such additional filtering increases manufacturing cost and may, depending on how the additional filtering is implemented, consume additional power. An undesirable trade off therefore exists between providing additional filtering and being able to receive at low input signal strengths. In some situations, due to the need to operate a low power levels in the passive mode, additional filtering cannot be employed and NFC communication range is limited.

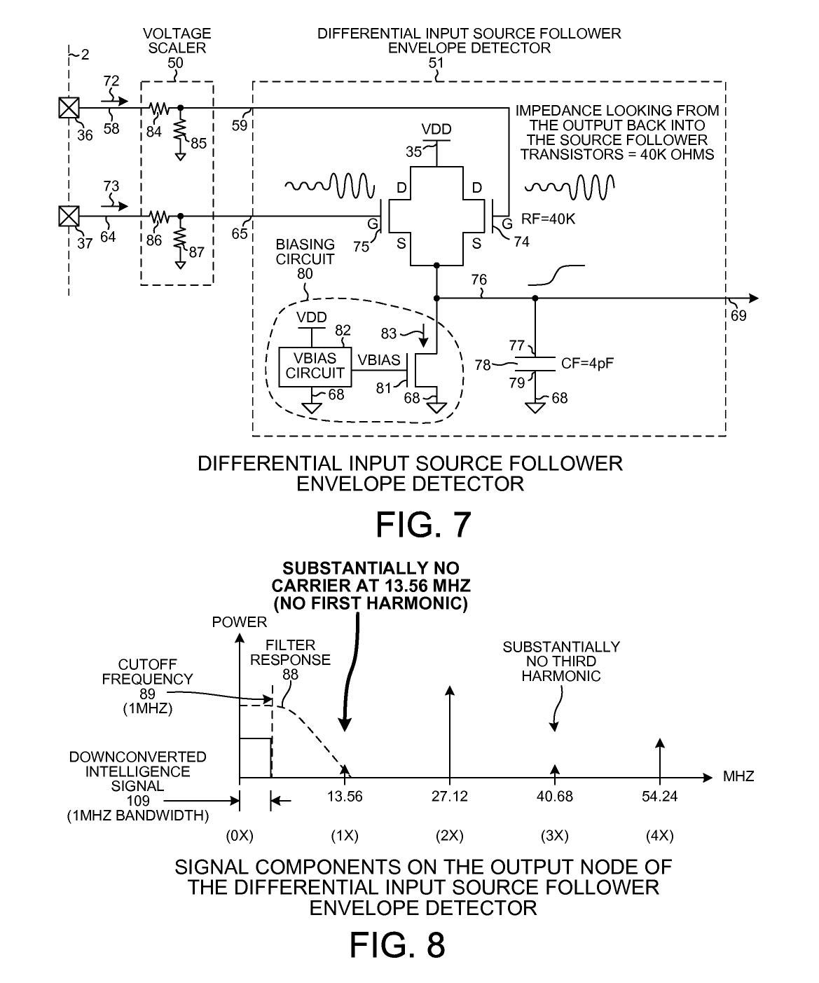

FIG. 7 is a simplified circuit diagram of the differential input source follower envelope detector 51 of FIG. 2. Arrow 72 represents the first signal originating from first terminal 54 of the NFC antenna after the signal has passed through the matching network 29 and onto terminal 36 of NFC integrated circuit 2. Similarly, arrow 73 represents the second signal originating from second terminal 60 of the NFC antenna after the signal has passed through the matching network 29 and onto terminal 37. First signal 72 passes through voltage scaler 50, onto the first input lead 59 of the differential input source follower envelope detector 51, and is supplied onto the gate of a first input transistor 74 of the envelope detector. Second signal 73 passes through voltage scaler 50, onto the second input lead 65 of the differential input source follower envelope detector 51, and is supplied onto the gate of a second input transistor 75 of the envelope detector. The first and second signals can be considered together to be a differential NFC input signal that includes an NFC intelligence signal that is modulated onto a higher frequency carrier signal. The NFC input signal has a peak-to-peak voltage amplitude that ranges from approximately 0.2 volts to approximately 1.0 volts. The NFC intelligence signal has a bandwidth of approximately one MHz. The carrier signal has a frequency of 13.56 MHz. The envelope detector 51 frequency demodulates the NFC input signal to downconvert the one MHz wide intelligence signal from RF frequency down to baseband without downconverting the carrier. In one advantageous aspect, substantially no signal of the frequency of the carrier is present on output node 76.

The drains of the transistors 74 and 75 are coupled together and to supply voltage conductor 35. The sources of the transistors 74 and 75 are coupled together at output node 76. A first lead 77 of a capacitor 78 is coupled to the sources of transistors 74 and 75 at output node 76. The second lead 79 of capacitor 78 is coupled to ground conductor 68. A biasing circuit 80 involving a bias transistor 81 and a voltage bias circuit 82 is set to draw a one microampere bias current 83 from output node 76 such that the transistors 74 and 75 are biased to operate in weak inversion. (Although transistors 74 and 75 are biased to operate in weak inversion in this example, these transistors may be biased to operate in strong inversion in other examples.) The output lead 69 of the envelope detector is coupled to the input lead 70 of the ADC 52 of the NFC data recovery circuit 53 as illustrated in FIG. 2. The resistors 84-87 of voltage scaler 50 have resistance values of 15K ohms and 1K ohms in this embodiment so that they reduce the amplitude of the NFC input signal by a factor of sixteen. The envelope detector 51 includes a low pass RC filter. The capacitance CF of the low pass RC filter is 4 pF. The impedance RF of the low pass RC filter is 40K ohms. This is the impedance looking back into the source follower from output node 76.

FIG. 8 is a diagram of the spectrum of the output signal on node 76. The one MHz wide NFC intelligence signal is downconverted from RF frequency and appears on output node 76 at baseband. Dashed line 88 represents the filter response of the RC filter of the envelope detector 51. The filter has a cutoff frequency 89 of one MHz. Due to the topology of the differential input source follower envelope detector 51, the odd harmonics of the carrier (including the fundamental) tend to cancel each other out on output node 76. FIG. 8 shows there being substantially no carrier signal present on output node 76 at frequency 1X (13.56 MHz). Similarly, FIG. 8 shows there being substantially no third harmonic of the carrier being present on output node 76 at 3X (40.68 MHz). Due to there being very little of the carrier present on output node 76, requirements on the low pass filtering of the envelope detector can be relaxed.

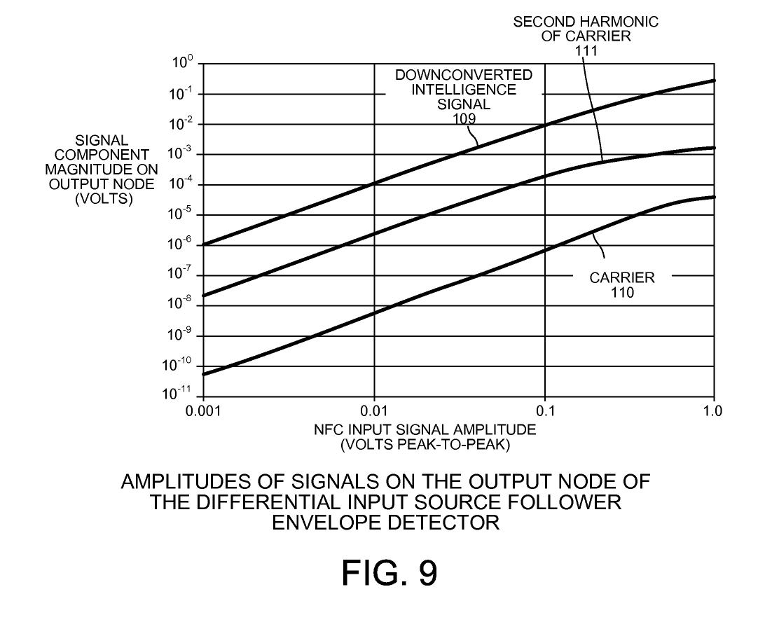

FIG. 9 is a diagram that illustrates an operation of the differential input source follower envelope detector 51 of FIG. 7. The vertical axis represents the voltage amplitude of a signal component on output node 76. The horizontal axis represents the peak-to-peak voltage amplitude of signal components on the output node 76 of the envelope detector 51. The horizontal axis has a logarithmic scale. As the magnitude of the NFC input signal decreases, so too do the magnitudes of the signal components on output node 76. This corresponds to proceeding from right to left in the diagram. Proceeding from right to left in the diagram, the amplitude of the carrier component 110 is seen to decrease in amplitude in the same way that the amplitude of the downconverted NFC intelligence signal 109 decreases. Unlike the situation illustrated in FIG. 5, the magnitude of the carrier signal 110 does not rise above the magnitude of downconverted intelligence signal 109 even as the amplitude of the NFC input signal decreases down to very low levels. Also note that the magnitude of the carrier 110 is very small. The magnitude of the carrier 110 in FIG. 9 is the lowest line whereas in the chart of FIG. 5 the carrier 110 was above the line of the second harmonic. Due to this very low amplitude, there is said to be substantially no signal at the carrier frequency on the output node 76.

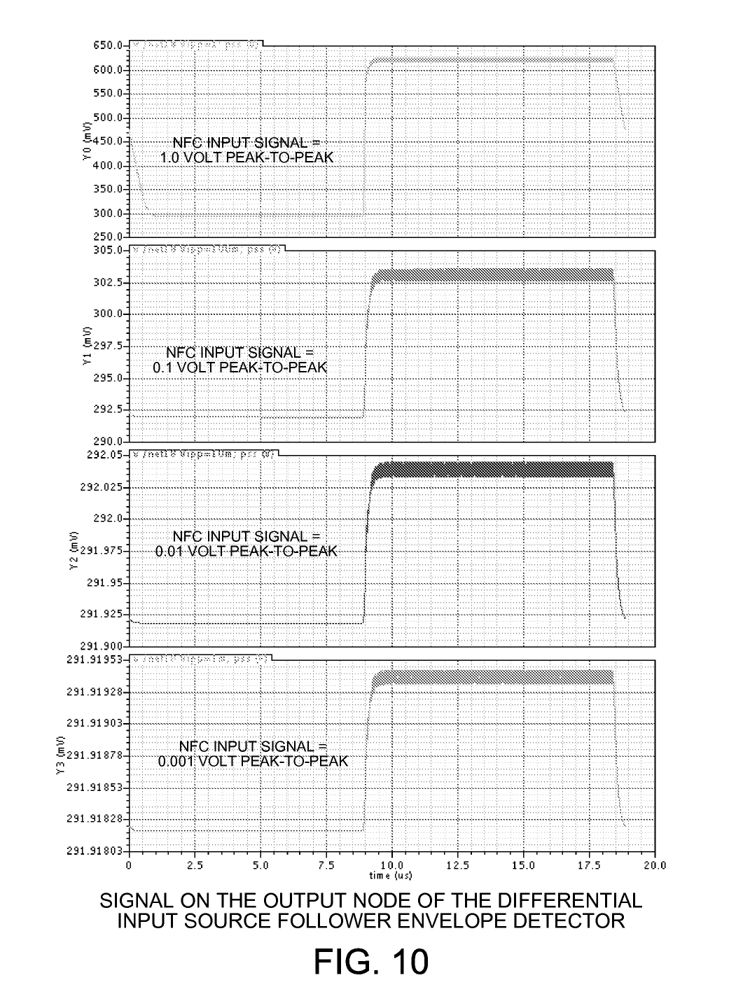

FIG. 10 is a set of four waveforms of the signal on output node 76 when a square wave signal having an initial low portion followed by a high portion is received onto the NFC antenna. The peak-to-peak NFC input signal amplitudes for the waveforms from top to bottom in FIG. 10 are 1.0 volt, 0.1 volts, 0.01 volts, and 0.001 volts. Note that the relative amount of carrier interference riding on the signal as output from the envelope detector increases only slightly as the amplitude of the NFC input signal decreases. Even in the situation of the low 0.001 volt peak-to-peak NFC input signal amplitude of the bottom waveform, the envelope of the NFC intelligence signal 109 is clearly differentiatable from the carrier interference riding on the signal.

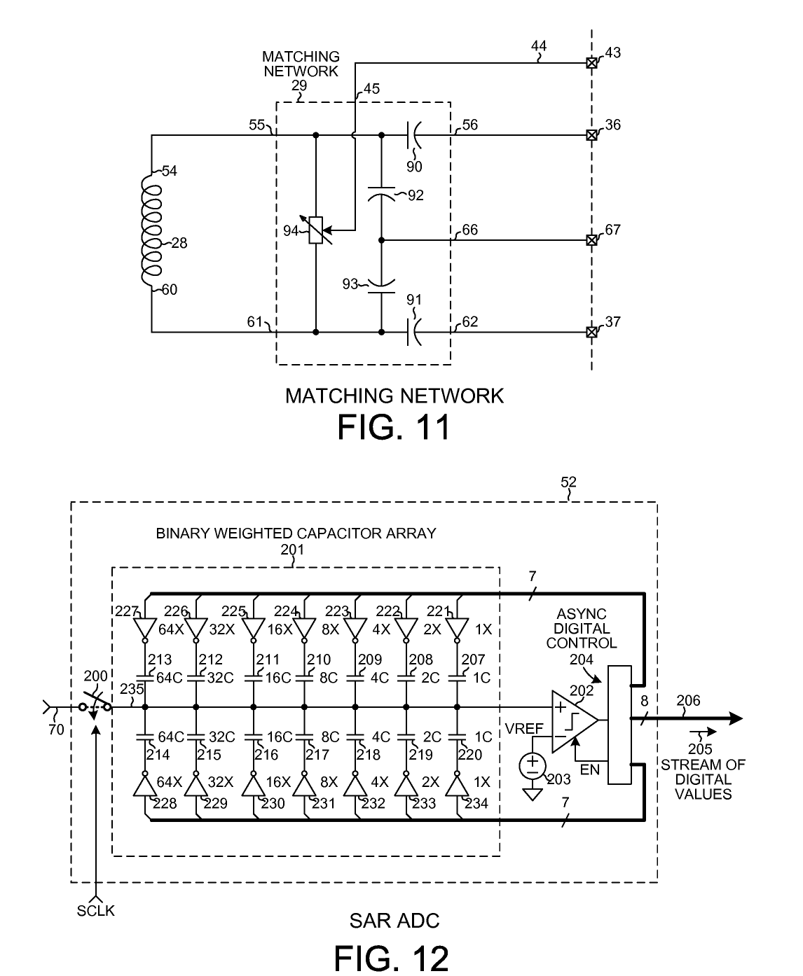

FIG. 11 is a more detailed diagram of the matching network 29 of FIG. 2. Matching network 29 includes four capacitances 90-93 and a variable impedance element 94. The variable impedance element has a selected one of two predetermined impedances as determined by the value of the digital LOAD MODULATION control signal received via terminal 45.

FIG. 12 is a detailed circuit diagram of one example of ADC 52 of FIG. 2. In this example, ADC 52 is an ultra-low power and small Successive Approximation ADC (SAR ADC) that consumes only a few microamperes (at 1.0 volts VDD) and is fabricated in approximately 0.1 square millimeter of integrated circuit area. The SAR ADC involves a switch 200, a binary weighted capacitor array 201, a one-bit quantizing comparator 202, a reference voltage generator 203, and an amount of asynchronous digital control logic 204. The SAR ADC receives an analog signal from the output node 76 of the differential input source follower envelope detector 51 via input lead 70 and outputs a corresponding stream 205 of eight-bit digital values onto output conductors 206. The binary weighted capacitor array 201 includes seven pairs of capacitors 207-220 and a corresponding seven pairs of inverters 221-234. The capacitors of each pair are of the same capacitance, but the capacitances of the pairs decrease in a binary fashion as indicated by the labels 64C, 32C, 16C, 8C, 4C, 2C and 1C. A first lead of each capacitor is coupled to the sample node 235. A second lead of each capacitor is coupled to an output of its corresponding inverter. Each of the inverters can be controlled to couple the second lead of its corresponding capacitor either to a ground conductor (at ground potential) or to a VDD supply voltage conductor (at supply voltage VDD).

To do an analog-to-digital conversion, switch 200 is initially closed by digital signal SCLK such that sample node 235 is charged to the same voltage that is being output by the differential input source follower envelope detector 51. All the inverters driving the capacitors of the upper row of capacitors in FIG. 12 are controlled to couple the second leads of the capacitors of the upper row to VDD, whereas all the inverters driving the second leads of the capacitors of the lower row of capacitors in FIG. 12 are controlled to couple the second leads of these capacitors of the lower row to ground. Once the capacitors are charged, then switch 200 is opened under control of digital signal SCLK. Asynchronous digital control logic 204 then detects whether the voltage on the sample node 235 is above or below the reference voltage VREF. If the voltage is above the voltage on the sample node 235, then the most significant bit is determined to be a digital one, otherwise the most significant bit is determined to be a digital zero. If the voltage on the sampling node was higher than VREF, then the inverter 227 driving the second lead of the capacitor 213 is switched to output a digital logic low onto the second lead of capacitor 213, whereas if the voltage on the sampling node was lower than VREF then the inverter 228 driving the second lead of the capacitor 214 is switched to output a digital logic high onto the second lead of capacitor 214.

The process is then repeated for the second most significant bit. Asynchronous digital control logic 204 detects whether the voltage on the sample node 235 is above or below the reference voltage VREF. If the voltage on the sample node 235 is above VREF, then the second most significant bit is determined to be a digital one, otherwise the second most significant bit is determined to be a digital zero. If the voltage on the sampling node was higher than VREF, then the inverter 226 driving the second lead of the capacitor 212 is switched to output a digital logic low onto the second lead of capacitor 212, whereas if the voltage on the sampling node was lower than VREF then the inverter 229 driving the second lead of the capacitor 215 is switched to output a digital logic high onto the second lead of capacitor 215.

This process is repeated for each of the seven pairs of capacitors until the values of most significant seven bits of the eight-bit output value of the SAR ADC have been determined. Once these seven bits have been determined and the inverters have been set appropriately, then the voltage on the sample node 235 is compared to VREF. The result of the comparison is the least significant bit of the eight-bit value as output onto output conductors 206. For additional information on the SAR ADC of FIG. 12, see: United States Patent Application Publication US2010/0141499, published Jun. 10, 2010, by Lennart K. Mathe.

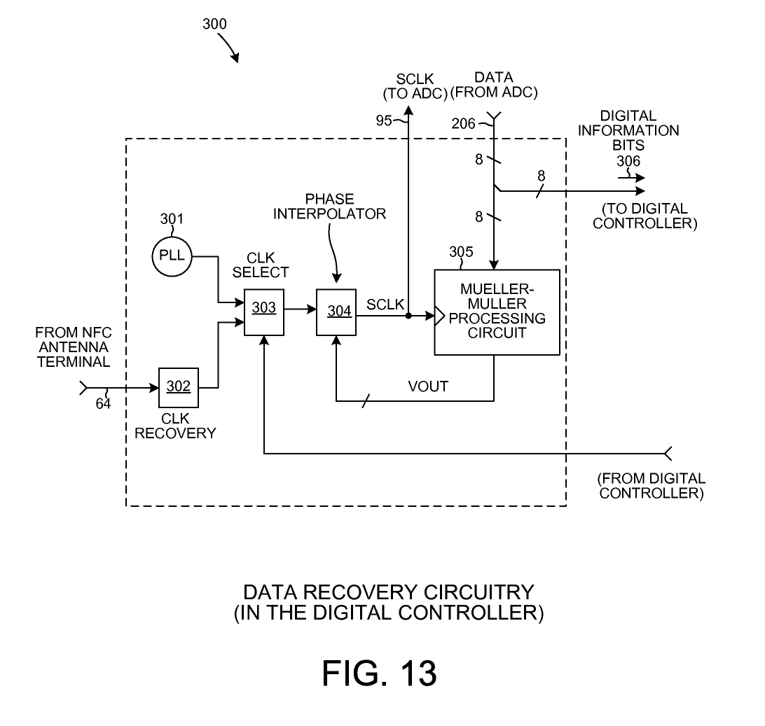

FIG. 13 is a simplified diagram of one example of data recovery circuitry 300 inside the digital controller 39 of FIG. 2. Data recovery circuitry 300 generates the signal SCLK and supplies it via conductor 95 to ADC 52. ADC 52 returns a stream of eight-bit values via conductors 206 back to the data recovery circuitry 300. Data recovery circuitry 300 includes a Phase-Locked Loop (PLL) 301, a clock recovery circuit 302, a clock select switch 303, a phase interpolator 304, and a Mueller-Muller processing circuit 305. Data recovery circuitry 300 receives the input signal from integrated circuit terminal 37 (see FIG. 2) via conductor 64. The result of the operation of the data recovery circuitry 300 is SCLK and recovered digital information bits 306. In this case, the recovered digital information bits 306 are the same digital values of the stream 205 of digital values as output from ADC 52. In operation, PLL 301 generates a clock signal that can be used to perform data recovery. Alternatively, clock recovery circuit 302 generates a clock signal from the NFC input signal and this clock signal is used to perform data recovery. CLK select circuit 303 selects which one of the two clock signals to use. In the passive mode, the recovered clock signal is used whereas in the active mode the PLL-generated clock signal is used. Phase interpolator 304 adjusts the delay of the clock based on multi-bit digital feedback signal VOUT coming from the Mueller-Muller processing circuit 305. The Mueller-Muller processing circuit 305 takes in the clock signal SCLK from the phase interpolator and the eight-bit data as received from the ADC 52, and determines the phase difference between them. The feedback action of VOUT adjusts the clock delay such that the data is sampled at the correct time by SCLK. This is called clock and data recovery because the resulting SCLK is the recovered clock with correct timing relative to the data signal.

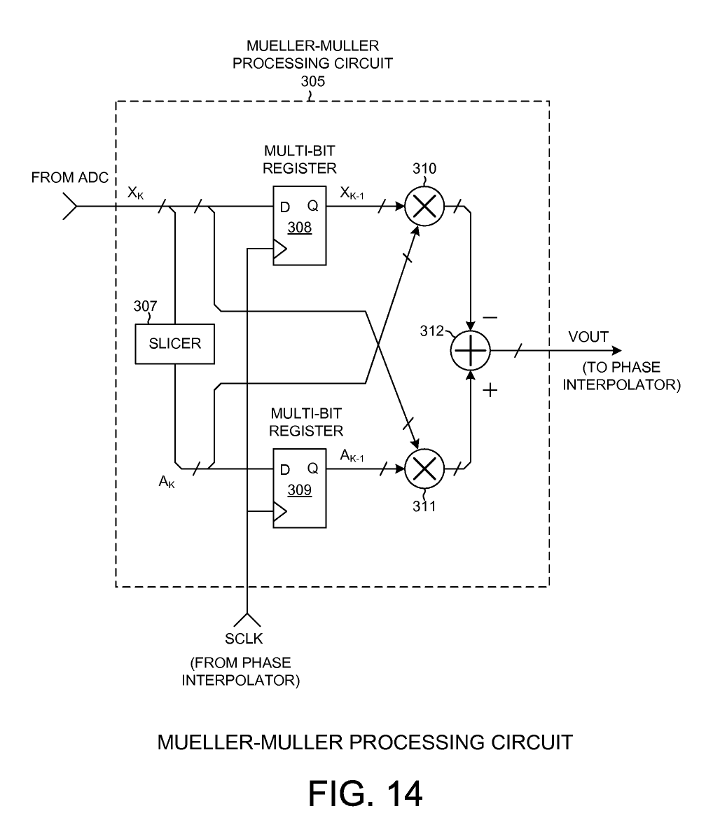

FIG. 14 is a simplified diagram of one example of the Mueller-Muller processing circuit 305 of FIG. 13. The circuit 305 includes a slicer 307, two multi-bit digital registers 308 and 309, two multi-bit digital multipliers 310 and 311, and a multi-bit digital summer 312.

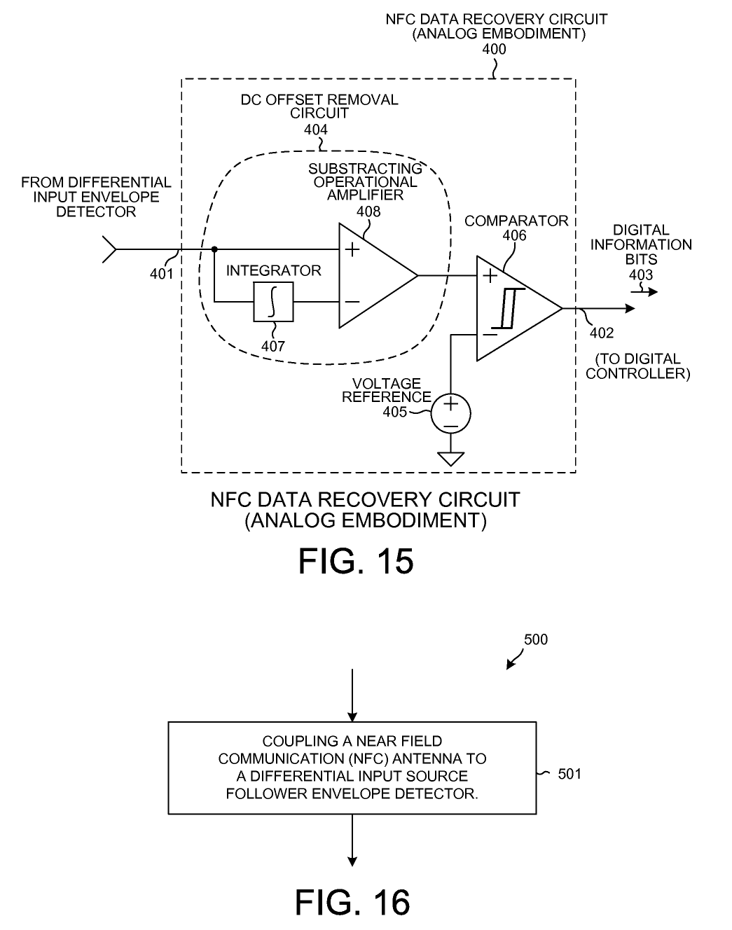

FIG. 15 is a diagram of one example of an analog embodiment 400 of the NFC data recovery circuit of FIG. 2. The analog embodiment 400 of FIG. 15 replaces the ADC 52 and data recovery circuitry 300 of FIG. 13. When the analog embodiment 400 is substituted, the input lead 401 of the analog embodiment 400 is coupled to the output lead 69 of the differential input source follower envelope detector 51 and the output lead 402 of the analog embodiment 400 supplies the extracted digital information bits 403 to the digital controller 39. The analog embodiment 400 includes a DC offset removal circuit 404, a reference voltage generator 405, and a comparator with hysteresis 406. The DC offset removal circuit 404 includes an integrator 407 that integrates the signal as output by the envelope detector 51. The output of the integrator 407 is the average voltage level of the envelope detector output signal. Subtracting operational amplifier 408 subtracts this average voltage level from the signal from the envelope detector, thereby removing any DC component of the signal. Comparator 406 compares the resulting signal to a reference voltage that is approximately midrange between the high limit of the signal as output by comparator 408 and the low limit of the signal as output by comparator 408. Reference voltage generator 405 generates this reference voltage and supplies it onto the non-inverting input lead of comparator 406. Accordingly, if the level of the signal as output by the DC offset removal circuit 404 is higher than the reference voltage, then comparator 406 rails high and outputs a high digital logic level signal. On the other hand, if the level of the signal as output by the DC offset removal circuit 404 is lower than the reference voltage, then comparator 406 rails low and outputs a low digital logic level signal.

FIG. 16 is a flowchart of a method 500 in accordance with one novel aspect. A Near Field Communication (NFC) antenna is coupled (step 501) to a differential input source follower envelope detector. In one example, the NFC antenna of the method 500 is NFC antenna 28 of FIG. 2, the differential input source follower envelope detector of the method 500 is the differential input source follower envelope detector 51 of FIG. 2 and of FIG. 7, and the terminals 54 and 60 of NFC antenna 28 are coupled to the input leads 59 and 65 of the differential input source follower envelope detector 51 via the matching network 29 and the voltage scaler 50 of FIG. 2. The differential input source follower envelope detector performs frequency demodulation to downconvert an NFC intelligence signal from RF frequency to baseband. There is no intervening RF frequency amplifier in the NFC input signal path between the NFC antenna and the differential input source follower envelope detector. In some cases, the differential input source follower envelope detector is followed by a digital NFC data recovery circuit (for example, involving a SAR ADC and a data recovery circuit as shown in FIG. 12 and FIG. 13). In other cases, the differential input source follower envelope detector is followed by an analog NFC data recovery circuit (for example, involving the analog circuit of FIG. 15). In one example, the method is a method of manufacturing a system involving the NFC integrated circuit 2 of FIG. 1.

Although certain specific embodiments are described above for instructional purposes, the teachings of this patent document have general applicability and are not limited to the specific embodiments described above. Although the term NFC properly applies to communications that comply with particular standards, the term NFC is used more generally and broadly in this patent document to describe any type of communication that employs near field effects to communicate information including, but not limited to, RFID communications and NFC communications, regardless of whether or not those communications comply partially or fully with RFID or NFC standards and protocols. The example of a one MHz wide NFC intelligence signal is set forth above only as an illustrative example. An actual NFC intelligence signal may have another bandwidth, such as a bandwidth in a range of from approximately 50 KHz to one MHz. Accordingly, various modifications, adaptations, and combinations of the various features of the described specific embodiments can be practiced without departing from the scope of the claims that are set forth below.

What is claimed is:

1. A method of manufacturing a system comprising:
coupling a Near Field Communication (NFC) antenna to a differential input envelope detector.

2. The method of manufacturing the system of claim 1, wherein the system is a mobile communication device, and wherein the differential input envelope detector is adapted to perform frequency demodulation to downconvert an NFC intelligence signal from a frequency band located at about 13.56 MHz to a baseband frequency band located at about zero hertz.

3. The method of manufacturing the system of claim 1, wherein the differential input envelope detector is a differential input source follower envelope detector.

4. The method of manufacturing the system of claim 1, wherein said coupling involves coupling the NFC antenna through a matching network and a voltage scaler to the differential input envelope detector.

5. The method of manufacturing the system of claim 1, further comprising:
providing a data recovery circuit that receives a signal output by the differential input envelope detector and recovers digital information bits from the signal.

6. The method of manufacturing the system of claim 5, wherein the data recovery circuit comprises:
an Analog-to-Digital Converter (ADC); and
a Mueller-Muller processing circuit that receives a stream of digital values output by the ADC.

7. The method of manufacturing the system of claim 5, wherein the data recovery circuit comprises:
an analog DC offset removal circuit; and
an analog comparator that receives a signal output by the analog DC offset removal circuit.

8. The method of manufacturing the system of claim 1, wherein a first signal from the NFC antenna is received onto a gate of a first transistor of the differential input envelope detector, wherein a second signal from the NFC antenna is received onto a gate of a second transistor of the differential input envelope detector, and wherein a source of the first transistor is coupled to a source of the second transistor.

9. The method of manufacturing the system of claim 8, wherein the first signal passes from a first terminal of the NFC antenna, through a matching network, through a voltage scaler circuit, and onto the gate of the first transistor, and wherein the second signal passes from a second terminal of the NFC antenna, through the matching network, through the voltage scaler circuit, and onto the gate of the second transistor.

10. A method of manufacturing an integrated circuit comprising:
providing a first terminal adapted to receive a first signal from a Near Field Communication (NFC) antenna;
providing a second terminal adapted to receive a second signal from the NFC antenna; and
fabricating a differential input envelope detector such that a first input lead of the differential input envelope detector is coupled to the first terminal and such that a second input lead of the differential input envelope detector is coupled to the second terminal, wherein the first terminal, the second terminal and the differential input envelope detector are parts of the integrated circuit.

11. The method of manufacturing the integrated circuit of claim 10, wherein the first terminal is coupled to the first input lead of the differential input envelope detector via a voltage scaler circuit, wherein the second terminal is coupled to second input lead of the differential input envelope detector via the voltage scaler circuit, and wherein the voltage scaler circuit is also a part of the integrated circuit.

12. The method of manufacturing the integrated circuit of claim 10, further comprising:
fabricating a data recovery circuit such that an output lead of the differential input envelope detector is coupled to an input lead of the data recovery circuit.

13. The method of manufacturing the integrated circuit of claim 10, further comprising:
fabricating an NFC energy harvesting circuit coupled to power the differential input envelope detector in a passive mode of operation of the integrated circuit.

14. The method of manufacturing the integrated circuit of claim 10, wherein the integrated circuit is an NFC communication device adapted to receive an NFC communication from the NFC antenna and to recover digital information bits from the NFC communication.

15. The method of manufacturing the integrated circuit of claim 10, wherein the differential input envelope detector is adapted to perform frequency demodulation to downconvert an NFC intelligence signal from a frequency band located at about 13.56 MHz to a baseband frequency band located at about zero hertz.

16. An integrated circuit comprising:
a first terminal;
a second terminal;
a differential input envelope detector circuit coupled to receive a first signal from the first terminal and coupled to receive a second signal from the second terminal; and
a Near Field Communication (NFC) data recovery circuit coupled to receive a signal from the differential input envelope detector circuit.

17. The integrated circuit of claim 16, further comprising:
an NFC energy harvesting circuit adapted to power the differential input envelope detector circuit in a passive mode of operation of the integrated circuit.

18. The integrated circuit of claim 16, further comprising:
a voltage scaler circuit coupled to supply the first signal from the first terminal onto a first input lead of the differential input envelope detector circuit and coupled to supply the second signal from the second terminal onto a second input lead of the differential input envelope detector circuit.

19. The integrated circuit of claim 16, wherein the NFC data recovery circuit comprises:
an Analog-to-Digital Converter (ADC); and
a Mueller-Muller processing circuit coupled to receive a stream of digital values output by the ADC.

20. The integrated circuit of claim 16, wherein the NFC data recovery circuit comprises:
an analog DC offset removal circuit that outputs an analog signal; and
an analog comparator that receives the analog signal output by the analog DC offset removal circuit.

21. The integrated circuit of claim 16, wherein the differential input envelope detector comprises:
a first transistor having a gate, a source and a drain, wherein the first signal is received onto the gate of the first transistor; and
a second transistor having a gate, a source and a drain, wherein the second signal is received onto the gate of the second transistor, wherein the source of the second transistor is coupled to the source of the first transistor.

22. The integrated circuit of claim 21, wherein the differential input envelope detector further comprises:
a capacitor having a first lead and a second lead, wherein the first lead is coupled to the source of the first transistor and to the source of the second transistor, and wherein the second lead is coupled to a ground conductor.

23. The integrated circuit of claim 21, wherein the drain of the first transistor is coupled to the drain of the second transistor and to a supply voltage conductor.

24. The integrated circuit of claim 22, wherein the differential input envelope detector further comprises:
a biasing circuit coupled to draw a bias current from a node of the differential input envelope detector, wherein the node includes the source of the first transistor, the source of the second transistor, and the first lead of the capacitor.

25. The integrated circuit of claim 21, wherein the signal received by the NFC data recovery circuit is present on an input lead of the NFC data recovery circuit, and wherein the input lead of the NFC data recovery circuit is coupled to the sources of the first and second transistors.

26. An apparatus comprising:
means for receiving an unamplified differential Near Field Communication (NFC) input signal from an NFC antenna and for performing frequency demodulation such that an NFC intelligence signal is downconverted, wherein the NFC input signal includes the NFC intelligence signal modulated on a carrier signal, wherein the carrier signal has a frequency, and wherein the means is also for outputting the downconverted NFC intelligence signal onto an output node with substantially no signal of the frequency being present on the output node; and
a Near Field Communication (NFC) data recovery circuit that receives the downconverted NFC intelligence signal from the output node.

27. The apparatus of claim 26, wherein the apparatus is an integrated circuit, and wherein the NFC antenna is not a part of the integrated circuit.

28. The apparatus of claim 26, wherein the apparatus is a mobile communication device, and wherein the NFC antenna is a part of the mobile communication device.

29. The apparatus of claim 26, wherein the means includes a differential input envelope detector, a first integrated circuit terminal coupled to a first input lead of the differential input envelope detector, and a second integrated circuit terminal coupled to a second input lead of the differential input envelope detector.
